(19) United States
(12) Patent Application Publication
(10) Pub. No.: US 2017/0038653 A1
(43) Pub. Date: Feb. 9, 2017

(54) METHOD FOR MANUFACTURING COA LIQUID CRYSTAL PANEL AND COA LIQUID CRYSTAL PANEL

(71) Applicant: Shenzhen China Star Optoelectronics Technology Co., Ltd., Shenzhen City, GD (CN)

(72) Inventors: Hongyuan XU, Shenzhen City (CN); Bo SUN, Shenzhen City (CN)

(73) Assignee: Shenzhen China Star Optoelectronics Technology Co. , Ltd., Shenzhen City (CN)

(21) Appl. No.: 14/758,563

(22) PCT Filed: Apr. 3, 2015
(86) PCT No.: PCT/CN2015/075852

§ 371 Date: Jun. 29, 2015

(30) Foreign Application Priority Data
Mar. 18, 2015 (CN) 201510119444.1

(51) Int. Cl. G02F 1/1362; H01L 27/12; H01L 29/786; G02F 1/1333; G02F 1/1343

(52) U.S. Cl. CPC G02F 1/136286; G02F 1/133345; G02F 1/136227; G02F 1/13439; H01L 29/78633; H01L 27/124; H01L 27/1248; G02F 2001/136222; G02F 2001/133302; G02F 2001/134345; G02F 2202/103; G02F 2202/104; G02F 2001/133357; G02F 2201/52; G02F 2202/02; G02F 2201/121; G02F 2201/123

(57) ABSTRACT

The present invention provides a method for manufacturing a COA liquid crystal panel and a COA liquid crystal panel. The method includes forming a planarization layer on a color resist layer to eliminate height difference resulting from stacking or overlapping of adjacent color resist blocks and also includes forming a pixel electrode layer on the planarization layer to set a pixel electrode block thereof located above sub pixel zones in such a way that a lateral border thereof is located above a scan line and a longitudinal border thereof is located above a signal line, whereby the array substrate achieves self-shielding of leaking light in the lateral direction by means of the scan line and also achieve self-shielding of leaking light in the longitudinal direction by means of the signal line and thus no black matrix is necessary is shielding leaking light. As such, the manufacturing process is simplified, the aperture ratio is heightened, and a gate terminal and an amorphous silicon layer are respectively formed on upper and lower sides of the poly-silicon layer to shield light, preventing light leakage from occurring in the site of a channel to affect the liquid crystal layer and also to prevent light leakage caused by misalignment between an array substrate and a glass substrate or panel flexing of a curved display device.

### BACKGROUND OF THE INVENTION

1. Field of the Invention

The present invention relates to the field of display technology, and in particular to a method for manufacturing a color filter on array (COA) liquid crystal panel and a COA liquid crystal panel.

2. The Related Arts

Liquid crystal displays (LCDs) have a variety of advantages, such as thin device body, low power consumption, and being free of radiation, and are thus of wide applications, such as liquid crystal televisions, mobile phones, personal digital assistants (PDAs), digital cameras, computer monitors, and notebook computer screens. A liquid crystal display generally comprises an enclosure, a liquid crystal panel arranged in the enclosure, and a backlight module mounted in the enclosure. The liquid crystal panel has a structure that is composed of a thin-film transistor (TFT) array substrate, a color filter (CF) substrate, and a layer of liquid crystal arranged between the two substrates and the operation principle thereof is that a drive voltage is applied to the two glass substrates to control the rotation of liquid crystal molecules of the liquid crystal layer in order to refract light from the backlight module out to generate an image.

Low temperature poly-silicon (LTPS) TFT technology is a novel technique, which, as an advantage thereof, when compared to amorphous silicon (a-Si) and oxide types of TFT, has an increased electron mobility and may enhance the driving performance of a display and reduce power consumption. The contemporary mainstream of the LTPS TFT is a top gate structure, which when used as a liquid crystal panel for displaying purposes, due to no light shielding layer arranged under a TFT channel, may generate a light induced leakage current in the channel. A conventional solution to prevent the photo-electric current is to first deposit a layer of amorphous silicon on the glass substrate to serve as a protection layer that might absorb the light or to directly deposit a layer of metal to block the light. However, in a regular structure of an array substrate, at the site above the location of the TFT, liquid crystal may suffer random orientation due to terrain irregularity and lacking of control voltage. Shielding much be provided by arranging a black matrix of a large area on one side of the CF substrate.

COA is a technique that allows a color resist layer of the CF substrate to be formed on the array substrate. The COA structure helps reduce coupling between a pixel electrode and metal wiring so that signal delay on the metal wiring may be improved. The COA structure may significantly reduce the parasitic capacitance and increase the aperture ratio and thus improve the displaying quality of the panel.

Referring to FIG. 1, a schematic cross-sectional view is given to illustrate a conventional COA liquid crystal panel, which generally comprises an array substrate 100, a glass substrate 200 arranged opposite to the array substrate 100, and a liquid crystal layer 300 arranged between the array substrate 100 and the glass substrate 200.

FIG. 2 is a top plan view of the array substrate 100 of the COA liquid crystal panel shown in FIG. 1. The array substrate 100 comprises red, green, and blue sub pixel zones. Each of the sub pixel zones comprises a base plate 110, an amorphous silicon layer 210 formed on the base plate 110, a buffer layer 310 formed on the amorphous silicon layer 210 and the base plate 110, a poly-silicon layer 400 formed on the buffer layer 310 and located above the amorphous silicon layer 210, a gate insulation layer 510 formed on the poly-silicon layer 400 and the buffer layer 310, a gate terminal 500 formed on the gate insulation layer 510 and located above the poly-silicon layer 400, an interlayer insulation layer 520 formed on the gate terminal 500 and the gate insulation layer 510, source/drain terminals 600 formed on the interlayer insulation layer 520, a signal line 700 formed the interlayer insulation layer 520 and spaced from the source/drain terminals 600, a passivation layer 530 formed on the source/drain terminals 600, the signal line 700, and the interlayer insulation layer 520, a color resist layer 540 formed on the passivation layer 530, and a pixel electrode layer 800 formed on the color resist layer 540.

The poly-silicon layer 400 comprises a channel 430, two N-type light doping areas 410 located on two opposite sides of the channel 430, and two N-type heavy doping areas 420 located on outer sides of the two N-type light doping areas 410. The interlayer insulation layer 520 and the gate insulation layer 510 comprise first vias 610 formed therethrough and located above the N-type heavy doping areas 420. The color resist layer 540 and the passivation layer 530 comprise a second via 810 formed therethrough and located above the source/drain terminals 600. The source/drain terminals 600 are respectively connected by the first vias 610 to the N-type heavy doping areas 420. The pixel electrode layer 800 is connected by the second via 810 to the source/drain terminals 600. The glass substrate 200 comprises a black matrix 910 formed thereon and a common electrode layer 900 is formed on the black matrix 910.

In the conventional COA liquid crystal panel, the color resist layer 540 comprises red, green, and blue color resist blocks corresponding to the red, green, and blue sub pixel zones. Adjacent ones of the color resist blocks must overlap each other to some extents during the manufacturing thereof, so as to form an intersection zone 640. Liquid crystal that is located above the intersection zone 640 may suffer incorrect orientation due to terrain variation. Thus, the intersection zone 640 must be shielded at the top side thereof by the black matrix 910 formed on the glass substrate 200. However, the arrangement of the black matrix 910 causes a loss of a large fraction of aperture ratio.

### SUMMARY OF THE INVENTION

An object of the present invention is to provide a method for manufacturing a color filter on array (COA) liquid crystal panel, which requires no additional formation of a black matrix so as to simplify the manufacturing process and increase aperture ratio and also help prevent leakage of light caused by incorrect alignment between an array substrate and a glass substrate or panel flexing of a curved display device.

Another object of the present invention is to provide a COA liquid crystal panel, which has a simple structure, a high aperture ratio, and reduced power consumption.

To achieve the above object, the present invention first provides a method for manufacturing a COA liquid crystal panel, which comprises the following steps:

(1) providing an array substrate and a glass substrate,

wherein the array substrate comprises red, green, and blue sub pixel zones and each of the sub pixel zones comprises a base plate, an amorphous silicon layer formed on the base plate, a buffer layer formed on the amorphous silicon layer and the base plate, a poly-silicon layer formed on the buffer layer and corresponding to the amorphous silicon layer, a gate insulation layer formed on the poly-silicon layer and the buffer layer, a gate terminal formed on the gate insulation layer and corresponding to the poly-silicon layer, a scan line formed on the gate insulation layer, an interlayer insulation layer formed on the gate terminal, the scan line, and the gate insulation layer, source/drain terminals formed on the interlayer insulation layer, and a signal line formed on the interlayer insulation layer and arranged to perpendicularly intersect the scan line in a horizontal direction, and

the interlayer insulation layer and the gate insulation layer comprise first vias formed therethrough at locations above the poly-silicon layer and the source/drain terminals are respectively set in engagement with the poly-silicon layer through the first vias;

(2) forming a passivation layer on the source/drain terminals, the signal line, and the interlayer insulation layer;

(3) forming a color resist layer on the passivation layer,

wherein the color resist layer comprises red, green, and blue color resist blocks respectively corresponding to the red, green, and blue sub pixel zone and two of the color resist blocks that are arranged to be adjacent to each other in a lateral direction form therebetween a first intersection zone, the first intersection zone being located above the signal line, and two of the color resist blocks that are arranged to be adjacent to each other in a longitudinal direction form therebetween a second intersection zone, the second intersection zone being located above the scan line;

(4) forming a planarization layer on the color resist layer and forming a second via in the planarization layer, the color resist layer, and the passivation layer to be located above the source/drain terminals;

(5) depositing and patterning a pixel electrode layer on the planarization layer and forming a common electrode layer on the glass substrate,

wherein the pixel electrode layer is set in engagement with the source/drain terminals through the second via and the pixel electrode layer comprises a pixel electrode block corresponding to the sub pixel zones and the pixel electrode block has a lateral border located above the scan line and a longitudinal border located above the signal line; and

(6) laminating the array substrate and the glass substrate with each other and filling therebetween a liquid crystal layer.

The poly-silicon layer comprises a channel, two N-type light doping areas respectively located on opposite sides of the channel, and two N-type heavy doping areas respectively located on outer sides of the two N-type light doping areas. The first vias are arranged above and corresponding to the N-type heavy doping areas. The source/drain terminals are respectively connected by the first vias with the N-type heavy doping areas.

Step (2) uses chemical vapor deposition to form the passivation layer.

Step (3) uses a coating process to form the color resist layer.

Step (4) uses a coating process to form the planarization layer. The planarization layer is formed of a transparent organic material.

Step (5) uses physical vapor deposition to form the pixel electrode layer. The pixel electrode layer and the common electrode layer are both formed of a material of indium tin oxide.

The present invention also provides a COA liquid crystal panel, which comprises an array substrate, a glass substrate arranged opposite to the array substrate, and a liquid crystal layer arranged between the array substrate and the glass substrate;

wherein the array substrate comprises red, green, and blue sub pixel zones, each of the sub pixel zones comprising a base plate, an amorphous silicon layer formed on the base plate, a buffer layer formed on the amorphous silicon layer and the base plate, a poly-silicon layer formed on the buffer layer and corresponding to the amorphous silicon layer, a gate insulation layer formed on the poly-silicon layer and the buffer layer, a gate terminal formed on the gate insulation layer and corresponding to the poly-silicon layer, a scan line formed on the gate insulation layer, an interlayer insulation layer formed on the gate terminal, the scan line, and the gate insulation layer, source/drain terminals formed on the interlayer insulation layer, a signal line formed on the interlayer insulation layer and arranged to perpendicularly intersect the scan line in a horizontal direction, a passivation layer formed on the source/drain terminals, the signal line, and the interlayer insulation layer, a color resist layer formed on the passivation layer, a planarization layer formed on the color resist layer, and a pixel electrode layer formed on the planarization layer;

the interlayer insulation layer and the gate insulation layer comprise first vias formed therethrough at locations above the poly-silicon layer, the planarization layer, the color resist layer, and the passivation layer comprising a second via formed therethrough at a location above the source/drain terminals, the source/drain terminals being respectively set in engagement with the poly-silicon layer through the first vias, the pixel electrode layer being set in engagement with the source/drain terminals through the second via; and

the color resist layer comprises red, green, and blue color resist blocks respectively corresponding to the red, green, and blue sub pixel zones, two of the color resist blocks that are arranged to be adjacent to each other in a lateral direction forming therebetween a first intersection zone, the first intersection zone being located above the signal line, two of the color resist blocks that are arranged to be adjacent to each other in a longitudinal direction forming therebetween a second intersection zone, the second intersection zone being located above the scan line, the pixel electrode layer comprising a pixel electrode block corresponding to the sub pixel zones, the pixel electrode block having a lateral border located above the scan line and a longitudinal border located above the signal line.

The poly-silicon layer comprises a channel, two N-type light doping areas respectively located on opposite sides of the channel, and two N-type heavy doping areas respectively located on outer sides of the two N-type light doping areas. The first vias are arranged above and corresponding to the N-type heavy doping areas. The source/drain terminals are respectively connected by the first vias with the N-type heavy doping areas.

The planarization layer is formed of a transparent organic material.

The glass substrate comprises a common electrode layer formed thereon and the pixel electrode layer and the common electrode layer are both formed of a material of indium tin oxide.

The present invention further provides a COA liquid crystal panel, which comprises an array substrate, a glass substrate arranged opposite to the array substrate, and a liquid crystal layer arranged between the array substrate and the glass substrate;

wherein the array substrate comprises red, green, and blue sub pixel zones, each of the sub pixel zones comprising a base plate, an amorphous silicon layer formed on the base plate, a buffer layer formed on the amorphous silicon layer and the base plate, a poly-silicon layer formed on the buffer layer and corresponding to the amorphous silicon layer, a gate insulation layer formed on the poly-silicon layer and the buffer layer, a gate terminal formed on the gate insulation layer and corresponding to the poly-silicon layer, a scan line formed on the gate insulation layer, an interlayer insulation layer formed on the gate terminal, the scan line, and the gate insulation layer, source/drain terminals formed on the interlayer insulation layer, a signal line formed on the interlayer insulation layer and arranged to perpendicularly intersect the scan line in a horizontal direction, a passivation layer formed on the source/drain terminals, the signal line, and the interlayer insulation layer, a color resist layer formed on the passivation layer, a planarization layer formed on the color resist layer, and a pixel electrode layer formed on the planarization layer;

the interlayer insulation layer and the gate insulation layer comprise first vias formed therethrough at locations above the poly-silicon layer, the planarization layer, the color resist layer, and the passivation layer comprising a second via formed therethrough at a location above the source/drain terminals, the source/drain terminals being respectively set in engagement with the poly-silicon layer through the first vias, the pixel electrode layer being set in engagement with the source/drain terminals through the second via;

the color resist layer comprises red, green, and blue color resist blocks respectively corresponding to the red, green, and blue sub pixel zones, two of the color resist blocks that are arranged to be adjacent to each other in a lateral direction forming therebetween a first intersection zone, the first intersection zone being located above the signal line, two of the color resist blocks that are arranged to be adjacent to each other in a longitudinal direction forming therebetween a second intersection zone, the second intersection zone being located above the scan line, the pixel electrode layer comprising a pixel electrode block corresponding to the sub pixel zones, the pixel electrode block having a lateral border located above the scan line and a longitudinal border located above the signal line;

wherein the poly-silicon layer comprises a channel, two N-type light doping areas respectively located on opposite sides of the channel, and two N-type heavy doping areas respectively located on outer sides of the two N-type light doping areas, the first vias being arranged above and corresponding to the N-type heavy doping areas, the source/drain terminals being respectively connected by the first vias with the N-type heavy doping areas; and

wherein the planarization layer is formed of a transparent organic material.

The efficacy of the present invention is that the present invention provides a COA liquid crystal panel and a manufacturing method thereof, in which through a planarization layer formed on a color resist layer, a height difference caused by stacking or overlapping of adjacent color resist blocks is eliminated and through a pixel electrode layer formed on the planarization layer in such a way that a pixel electrode block of the pixel electrode layer located above sub pixel zones has a lateral border located above a scan line and a longitudinal border located above a signal line, whereby the array substrate achieves self-shielding of leaking light in the lateral direction by means of the scan line and also achieve self-shielding of leaking light in the longitudinal direction by means of the signal line and thus no black matrix is necessary is shielding leaking light. As such, the manufacturing process is simplified, the aperture ratio is heightened, and a gate terminal and an amorphous silicon layer are respectively formed on upper and lower sides of the poly-silicon layer to shield light, preventing light leakage from occurring in the site of a channel to affect the liquid crystal layer and also to prevent light leakage caused by misalignment between an array substrate and a glass substrate or panel flexing of a curved display device.

For better understanding of the features and technical contents of the present invention, reference will be made to the following detailed description of the present invention and the attached drawings. However, the drawings are provided for the purposes of reference and illustration and are not intended to impose limitations to the present invention.

### BRIEF DESCRIPTION OF THE DRAWINGS

The technical solution, as well as other beneficial advantages, of the present invention will be apparent from the following detailed description of embodiments of the present invention, with reference to the attached drawing. In the drawing:

FIG. 1 is a schematic cross-sectional view of a conventional color filter on array (COA) liquid crystal panel;

FIG. 2 is a top plan view of an array substrate of the conventional COA liquid crystal panel shown in FIG. 1;

FIG. 3 is a flow chart illustrating a method for manufacturing a COA liquid crystal panel according to the present invention;

FIG. 4 is a schematic view illustrating step 1 of the method for manufacturing the COA liquid crystal panel according to the present invention;

FIG. 5 is a schematic view illustrating step 2 of the method for manufacturing the COA liquid crystal panel according to the present invention;

FIG. 6 is a schematic view illustrating step 3 of the method for manufacturing the COA liquid crystal panel according to the present invention;

FIG. 7 is a schematic view illustrating step 4 of the method for manufacturing the COA liquid crystal panel according to the present invention;

FIG. 8 is a schematic view illustrating step 5 of the method for manufacturing the COA liquid crystal panel according to the present invention;

FIG. 9 is a schematic view illustrating step 6 of the method for manufacturing the COA liquid crystal panel according to the present invention and is also a cross-sectional view of the COA liquid crystal panel according to the present invention; and

FIG. 10 is a top plan view showing an array substrate of the COA liquid crystal panel according to the present invention.

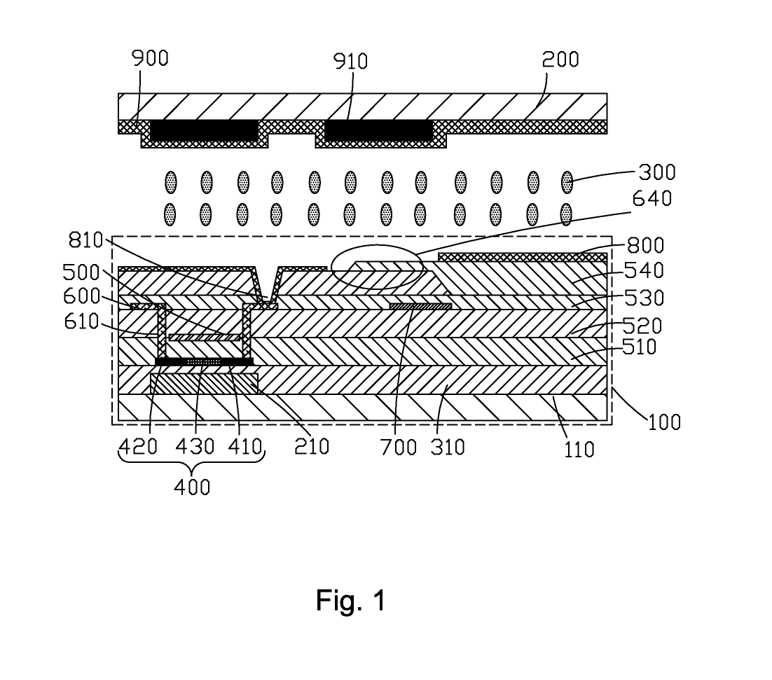

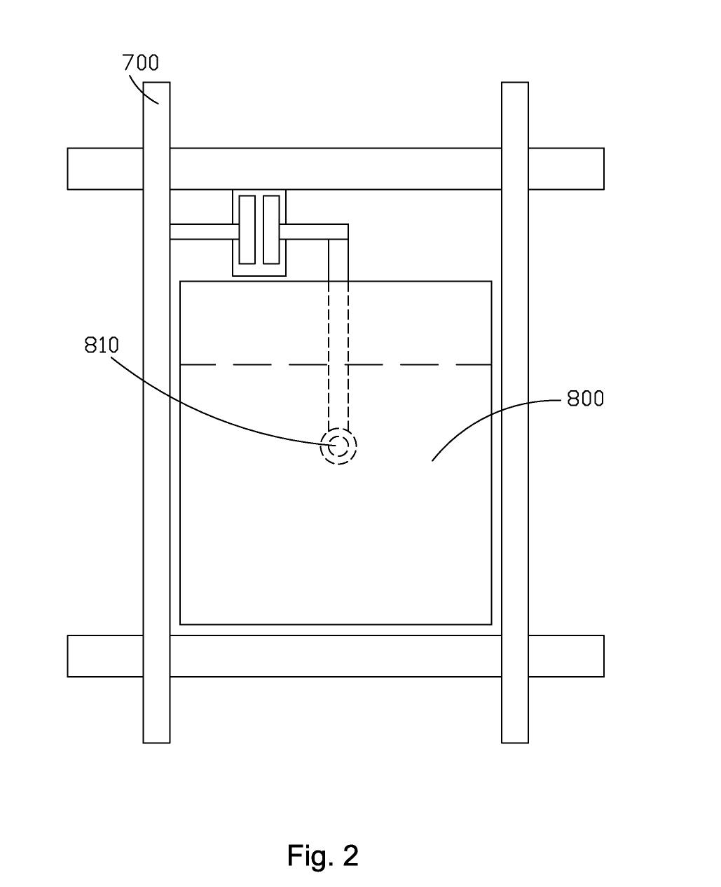

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

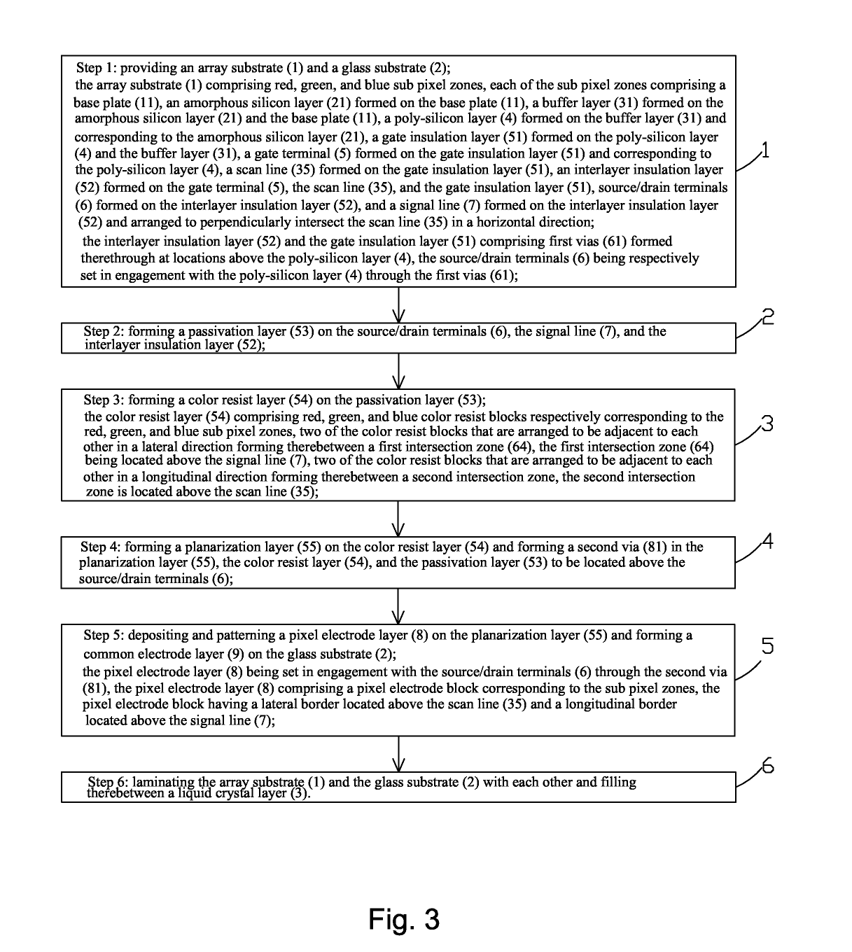

Referring to FIG. 3, the present invention provides a method for manufacturing a color filter on array (COA) liquid crystal panel, which comprises the following steps:

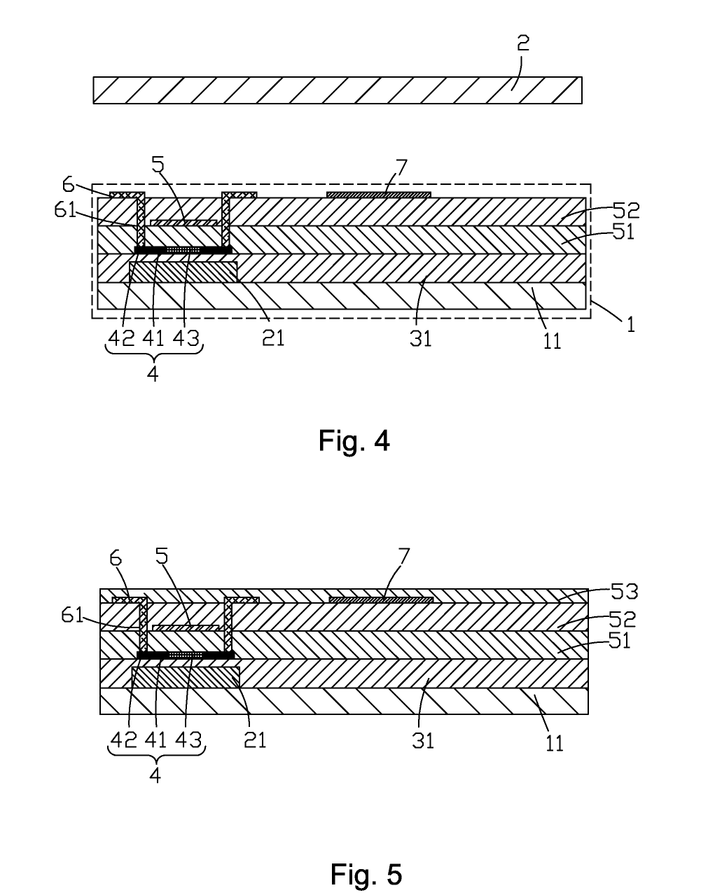

Step 1: as shown in FIG. 4, providing an array substrate 1 and a glass substrate 2.

Specifically, the array substrate 1 comprises red, green, and blue sub pixel zones. Each of the sub pixel zones comprises a base plate 11, an amorphous silicon layer 21 formed on the base plate 11, a buffer layer 31 formed on the amorphous silicon layer 21 and the base plate 11, a poly-silicon layer 4 formed on the buffer layer 31 and corresponding to the amorphous silicon layer 21, a gate insulation layer 51 formed on the poly-silicon layer 4 and the buffer layer 31, a gate terminal 5 formed on the gate insulation layer 51 and corresponding to the poly-silicon layer 4, a scan line 35 formed on the gate insulation layer 51, an interlayer insulation layer 52 formed on the gate terminal 5, the scan line 35, and the gate insulation layer 51, source/drain terminals 6 formed on the interlayer insulation layer 52, and a signal line 7 formed on the interlayer insulation layer 52 and arranged to perpendicularly intersect the scan line 35 in a horizontal direction.

The interlayer insulation layer 52 and the gate insulation layer 51 comprise first vias 61 formed therethrough at locations above the poly-silicon layer 4. The source/drain terminals 6 are respectively set in engagement with the poly-silicon layer 4 through the first vias 61.

Specifically, the poly-silicon layer 4 comprises a channel 43, two N-type light doping areas 41 respectively located on opposite sides of the channel 43, and two N-type heavy doping areas 42 respectively located on outer sides of the two N-type light doping areas 41. The first vias 61 are arranged above and corresponding to the N-type heavy doping areas 42. The source/drain terminals 6 are respectively connected by the first vias 61 with the N-type heavy doping areas 42.

Specifically, the signal line 7 and the scan line 35 are made of a metallic material of aluminum, molybdenum, or copper.

Step 2: as shown in FIG. 5, forming a passivation layer 53 on the source/drain terminals 6, the signal line 7, and the interlayer insulation layer 52.

Specifically, chemical vapor deposition (CVD) is used to form the passivation layer 53.

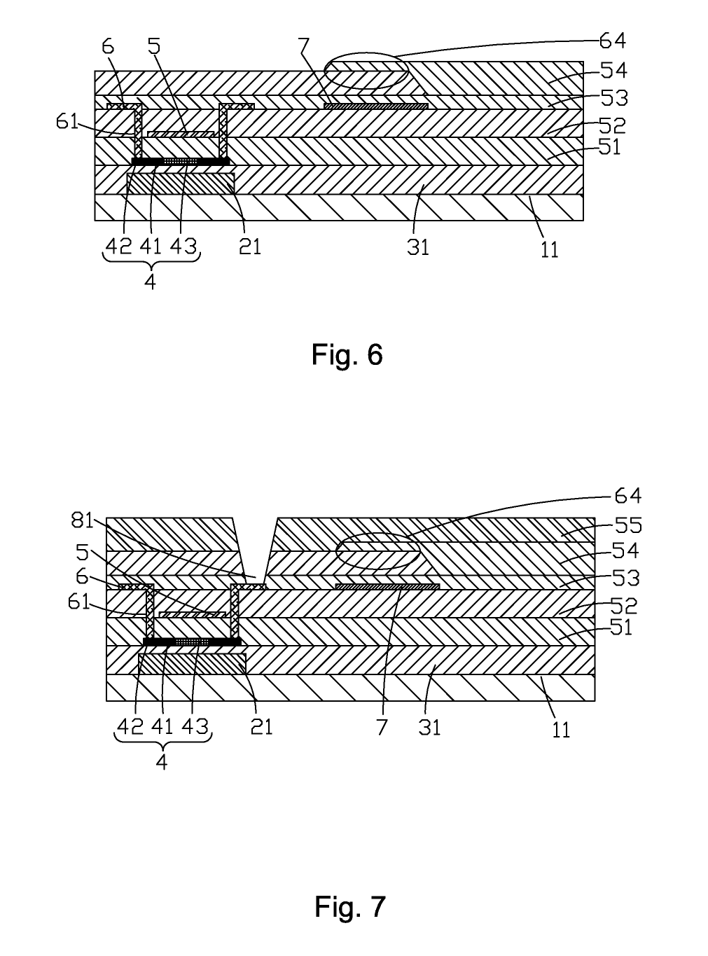

Step 3: as shown in FIG. 6, forming a color resist layer 54 on the passivation layer 53.

Specifically, the color resist layer 54 comprises red, green, and blue color resist blocks respectively corresponding to the red, green, and blue sub pixel zones. Two of the color resist blocks that are arranged to be adjacent to each other in a lateral direction form therebetween a first intersection zone 64 and the first intersection zone 64 is located above the signal line 7; and two of the color resist blocks that are arranged to be adjacent to each other in a longitudinal direction form therebetween a second intersection zone and the second intersection zone is located above the scan line 35, whereby black matrixes in the lateral direction and the longitudinal direction can be omitted and self-shielding of the scan line and the signal line can be achieved.

Specifically, a coating process is used to form the color resist layer 54.

Step 4: as shown in FIG. 7, forming a planarization layer 55 on the color resist layer 54 and forming a second via 81 in the planarization layer 55, the color resist layer 54, and the passivation layer 53 to be located above the source/drain terminals 6.

Specifically, a coating process is used to form the planarization layer 55 and the planarization layer 55 is formed of a transparent organic material.

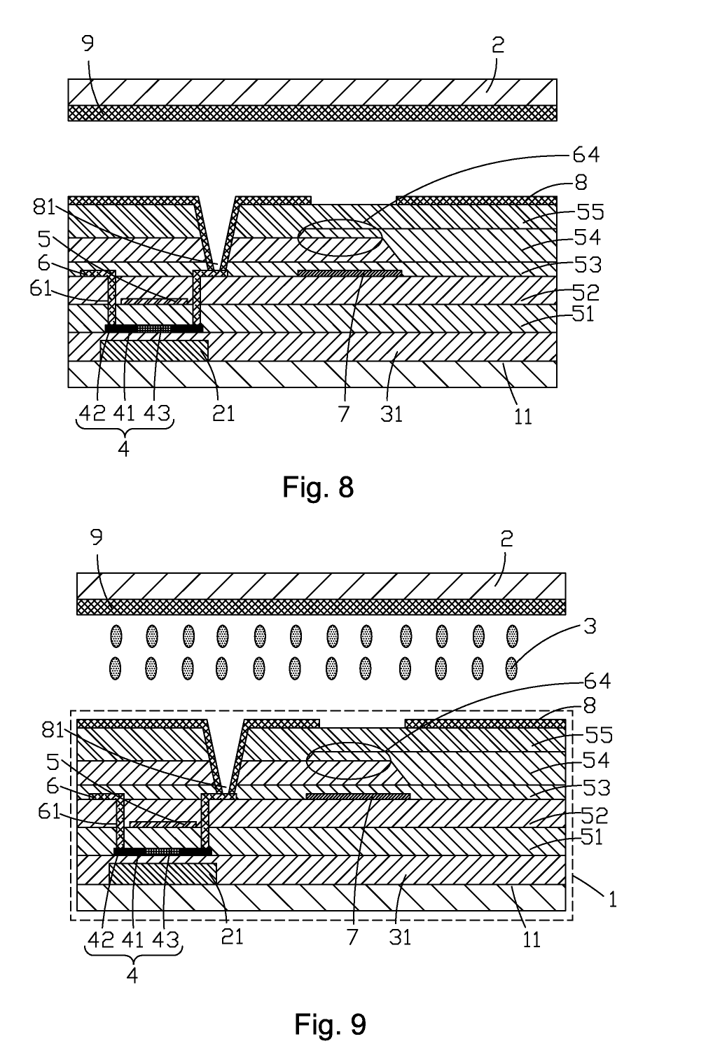

Step 5: as shown in FIG. 8, depositing and patterning a pixel electrode layer 8 on the planarization layer 55 and forming a common electrode layer 9 on the glass substrate 2.

The pixel electrode layer 8 is set in engagement with the source/drain terminals 6 through the second via 81. The pixel electrode layer 8 comprises a pixel electrode block corresponding to the sub pixel zones and the pixel electrode block has a lateral border located above the scan line 35 and a longitudinal border located above the signal line 7.

Specifically, physical vapor deposition (PVD) is used to form the pixel electrode layer 8. The pixel electrode layer 8 and the common electrode layer 9 are made of a material of indium tin oxide (ITO).

Step 6: as shown in FIG. 9, laminating the array substrate 1 and the glass substrate 2 with each other and filling therebetween a liquid crystal layer 3.

Specifically, in aligning the array substrate 1 and the glass substrate 2 to each other, since black matrixes are omitted from the glass substrate 2, the process can be simplified and misalignment that leads to leakage of light may be avoided. Further, for a curved display device, light leakage caused by positional deviation of the black matrixes during flexing of the panel may also be avoided.

The above-described method for manufacturing the COA liquid crystal panel comprises forming a planarization layer on a color resist layer to eliminate height difference resulting from stacking or overlapping of adjacent color resist blocks and also comprises forming a pixel electrode layer on the planarization layer to set a pixel electrode block thereof located above sub pixel zones in such a way that a lateral border thereof is located above a scan line and a longitudinal border thereof is located above a signal line, whereby the array substrate achieves self-shielding of leaking light in the lateral direction by means of the scan line and also achieve self-shielding of leaking light in the longitudinal direction by means of the signal line and thus no black matrix is necessary is shielding leaking light. As such, the manufacturing process is simplified, the aperture ratio is heightened, and a gate terminal and an amorphous silicon layer are respectively formed on upper and lower sides of the poly-silicon layer to shield light, preventing light leakage from occurring in the site of a channel to affect the liquid crystal layer and also to prevent light leakage caused by misalignment between an array substrate and a glass substrate or panel flexing of a curved display device.

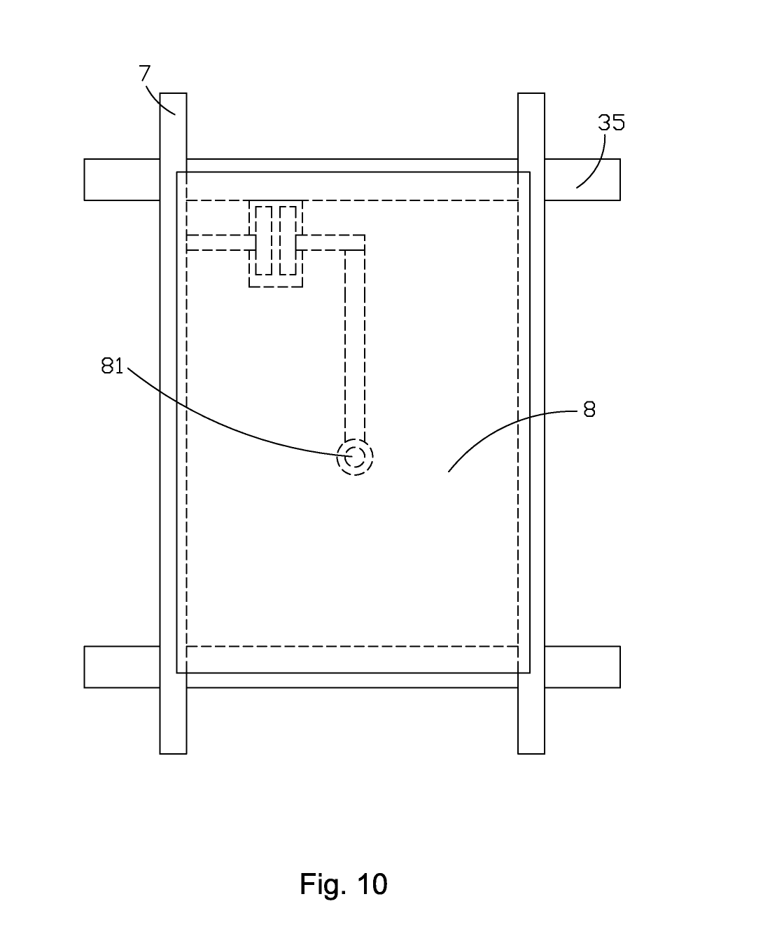

Referring collectively to FIGS. 9 and 10, the present invention also provides a COA liquid crystal panel, which comprises an array substrate 1, a glass substrate 2 arranged opposite to the array substrate 1, and a liquid crystal layer 3 arranged between the array substrate 1 and the glass substrate 2.

Specifically, the array substrate 1 comprises red, green, and blue sub pixel zones. Each of the sub pixel zones comprises a base plate 11, an amorphous silicon layer 21 formed on the base plate 11, a buffer layer 31 formed on the amorphous silicon layer 21 and the base plate 11, a poly-silicon layer 4 formed on the buffer layer 31 and corresponding to the amorphous silicon layer 21, a gate insulation layer 51 formed on the poly-silicon layer 4 and the buffer layer 31, a gate terminal 5 formed on the gate insulation layer 51 and corresponding to the poly-silicon layer 4, a scan line 35 formed on the gate insulation layer 51, an interlayer insulation layer 52 formed on the gate terminal 5, the scan line 35, and the gate insulation layer 51, source/drain terminals 6 formed on the interlayer insulation layer 52, a signal line 7 formed on the interlayer insulation layer 52 and arranged to perpendicularly intersect the scan line 35 in a horizontal direction, a passivation layer 53 formed on the source/drain terminals 6, the signal line 7, and the interlayer insulation layer 52, a color resist layer 54 formed on the passivation layer 53, a planarization layer 55 formed on the color resist layer 54, and a pixel electrode layer 8 formed on the planarization layer 55.

The interlayer insulation layer 52 and the gate insulation layer 51 comprise first vias 61 formed therethrough at locations above the poly-silicon layer 4. The planarization layer 55, the color resist layer 54, and the passivation layer 53 comprises a second via 81 formed therethrough at a location above the source/drain terminals 6. The source/drain terminals 6 are respectively set in engagement with the poly-silicon layer 4 through the first vias 61. The pixel electrode layer 8 is set in engagement with the source/drain terminals 6 through the second via 81.

Specifically, the poly-silicon layer 4 comprises a channel 43, two N-type light doping areas 41 respectively located on opposite sides of the channel 43, and two N-type heavy doping areas 42 respectively located on outer sides of the two N-type light doping areas 41. The first vias 61 are arranged above and corresponding to the N-type heavy doping areas 42. The source/drain terminals 6 are respectively connected by the first vias 61 with the N-type heavy doping areas 42.

The color resist layer 54 comprises red, green, and blue color resist blocks respectively corresponding to the red, green, and blue sub pixel zones. Two of the color resist blocks that are arranged to adjacent to each other in a lateral direction form therebetween a first intersection zone 64 and the first intersection zone 64 is located above the signal line 7. Two of the color resist blocks that are arranged to be adjacent to each other in a longitudinal direction form therebetween a second intersection zone and the second intersection zone is located above the scan line 35. The pixel electrode layer 8 comprises a pixel electrode block corresponding to the sub pixel zones and the pixel electrode block has a lateral border located above the scan line 35 and a longitudinal border located above the signal line 7.

Specifically, the planarization layer 55 is formed of a transparent organic material and the signal line 7 and the scan line 35 are made of a metallic material of aluminum, molybdenum, or copper.

Specifically, the glass substrate 2 comprises a common electrode layer 9 formed thereon. The pixel electrode layer 8 and the common electrode layer 9 are both formed of a material of indium tin oxide.

The above-described COA liquid crystal panel comprises a planarization layer formed on a color resist layer to eliminate height difference resulting from stacking or overlapping of adjacent color resist blocks and also comprises a pixel electrode layer formed on the planarization layer to set a pixel electrode block thereof located above sub pixel zones in such a way that a lateral border thereof is located above a scan line and a longitudinal border thereof is located above a signal line, whereby the array substrate achieves self-shielding of leaking light in the lateral direction by means of the scan line and also achieve self-shielding of leaking light in the longitudinal direction by means of the signal line and thus no black matrix is necessary is shielding leaking light. As such, the manufacturing process is simplified, the aperture ratio is heightened, and a gate terminal and an amorphous silicon layer are respectively formed on upper and lower sides of the poly-silicon layer to shield light, preventing light leakage from occurring in the site of a channel to affect the liquid crystal layer and also to prevent light leakage caused by misalignment between an array substrate and a glass substrate or panel flexing of a curved display device.

In summary, the present invention provides a COA liquid crystal panel and a manufacturing method thereof, in which through a planarization layer formed on a color resist layer, a height difference caused by stacking or overlapping of adjacent color resist blocks is eliminated and through a pixel electrode layer formed on the planarization layer in such a way that a pixel electrode block of the pixel electrode layer located above sub pixel zones has a lateral border located above a scan line and a longitudinal border located above a signal line, whereby the array substrate achieves self-shielding of leaking light in the lateral direction by means of the scan line and also achieve self-shielding of leaking light in the longitudinal direction by means of the signal line and thus no black matrix is necessary is shielding leaking light. As such, the manufacturing process is simplified, the aperture ratio is heightened, and a gate terminal and an amorphous silicon layer are respectively formed on upper and lower sides of the poly-silicon layer to shield light, preventing light leakage from occurring in the site of a channel to affect the liquid crystal layer and also to prevent light leakage caused by misalignment between an array substrate and a glass substrate or panel flexing of a curved display device.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A method for manufacturing a color filter on array (COA) liquid crystal panel, comprising the following steps:
(1) providing an array substrate and a glass substrate,
wherein the array substrate comprises red, green, and blue sub pixel zones and each of the sub pixel zones comprises a base plate, an amorphous silicon layer formed on the base plate, a buffer layer formed on the amorphous silicon layer and the base plate, a poly-silicon layer formed on the buffer layer and corresponding to the amorphous silicon layer, a gate insulation layer formed on the poly-silicon layer and the buffer layer, a gate terminal formed on the gate insulation layer and corresponding to the poly-silicon layer, a scan line formed on the gate insulation layer, an interlayer insulation layer formed on the gate terminal, the scan line, and the gate insulation layer, source/drain terminals formed on the interlayer insulation layer, and a signal line formed on the interlayer insulation layer and arranged to perpendicularly intersect the scan line in a horizontal direction, and
the interlayer insulation layer and the gate insulation layer comprise first vias formed therethrough at locations above the poly-silicon layer and the source/drain terminals are respectively set in engagement with the poly-silicon layer through the first vias;
(2) forming a passivation layer on the source/drain terminals, the signal line, and the interlayer insulation layer;
(3) forming a color resist layer on the passivation layer,
wherein the color resist layer comprises red, green, and blue color resist blocks respectively corresponding to the red, green, and blue sub pixel zone and two of the color resist blocks that are arranged to be adjacent to each other in a lateral direction form therebetween a first intersection zone, the first intersection zone being located above the signal line, and two of the color resist blocks that are arranged to be adjacent to each other in a longitudinal direction form therebetween a second intersection zone, the second intersection zone being located above the scan line;
(4) forming a planarization layer on the color resist layer and forming a second via in the planarization layer, the color resist layer, and the passivation layer to be located above the source/drain terminals;
(5) depositing and patterning a pixel electrode layer on the planarization layer and forming a common electrode layer on the glass substrate,
wherein the pixel electrode layer is set in engagement with the source/drain terminals through the second via and the pixel electrode layer comprises a pixel electrode block corresponding to the sub pixel zones and the pixel electrode block has a lateral border located above the scan line and a longitudinal border located above the signal line; and
(6) laminating the array substrate and the glass substrate with each other and filling therebetween a liquid crystal layer.

2. The method for manufacturing the COA liquid crystal panel as claimed in claim 1, wherein the poly-silicon layer comprises a channel, two N-type light doping areas respectively located on opposite sides of the channel, and two N-type heavy doping areas respectively located on outer sides of the two N-type light doping areas, the first vias being arranged above and corresponding to the N-type heavy doping areas, the source/drain terminals being respectively connected by the first vias with the N-type heavy doping areas.

3. The method for manufacturing the COA liquid crystal panel as claimed in claim 1, wherein step (2) uses chemical vapor deposition to form the passivation layer.

4. The method for manufacturing the COA liquid crystal panel as claimed in claim 1, wherein step (3) uses a coating process to form the color resist layer.

5. The method for manufacturing the COA liquid crystal panel as claimed in claim 1, wherein step (4) uses a coating process to form the planarization layer, the planarization layer being formed of a transparent organic material.

6. The method for manufacturing the COA liquid crystal panel as claimed in claim 1, wherein step (5) uses physical vapor deposition to form the pixel electrode layer, the pixel electrode layer and the common electrode layer being both formed of a material of indium tin oxide.

7. A color filter on array (COA) liquid crystal panel, comprising an array substrate, a glass substrate arranged opposite to the array substrate, and a liquid crystal layer arranged between the array substrate and the glass substrate;
wherein the array substrate comprises red, green, and blue sub pixel zones, each of the sub pixel zones comprising a base plate, an amorphous silicon layer formed on the base plate, a buffer layer formed on the amorphous silicon layer and the base plate, a poly-silicon layer formed on the buffer layer and corresponding to the amorphous silicon layer, a gate insulation layer formed on the poly-silicon layer and the buffer layer, a gate terminal formed on the gate insulation layer and corresponding to the poly-silicon layer, a scan line formed on the gate insulation layer, an interlayer insulation layer formed on the gate terminal, the scan line, and the gate insulation layer, source/drain terminals formed on the interlayer insulation layer, a signal line formed on the interlayer insulation layer and arranged to perpendicularly intersect the scan line in a horizontal direction, a passivation layer formed on the source/drain terminals, the signal line, and the interlayer insulation layer, a color resist layer formed on the passivation layer, a planarization layer formed on the color resist layer, and a pixel electrode layer formed on the planarization layer;
the interlayer insulation layer and the gate insulation layer comprise first vias formed therethrough at locations above the poly-silicon layer, the planarization layer, the color resist layer, and the passivation layer comprising a second via formed therethrough at a location above the source/drain terminals, the source/drain terminals being respectively set in engagement with the poly-silicon layer through the first vias, the pixel electrode layer being set in engagement with the source/drain terminals through the second via; and
the color resist layer comprises red, green, and blue color resist blocks respectively corresponding to the red, green, and blue sub pixel zones, two of the color resist blocks that are arranged to be adjacent to each other in a lateral direction forming therebetween a first intersection zone, the first intersection zone being located above the signal line, two of the color resist blocks that are arranged to be adjacent to each other in a longitudinal direction forming therebetween a second intersection zone, the second intersection zone being located above the scan line, the pixel electrode layer comprising a pixel electrode block corresponding to the sub pixel zones, the pixel electrode block having a lateral border located above the scan line and a longitudinal border located above the signal line.

8. The COA liquid crystal panel as claimed in claim 7, wherein the poly-silicon layer comprises a channel, two N-type light doping areas respectively located on opposite sides of the channel, and two N-type heavy doping areas respectively located on outer sides of the two N-type light doping areas, the first vias being arranged above and corresponding to the N-type heavy doping areas, the source/drain terminals being respectively connected by the first vias with the N-type heavy doping areas.

9. The COA liquid crystal panel as claimed in claim 7, wherein the planarization layer is formed of a transparent organic material.

10. The COA liquid crystal panel as claimed in claim 7, wherein the glass substrate comprises a common electrode layer formed thereon and the pixel electrode layer and the common electrode layer are both formed of a material of indium tin oxide.

11. A color filter on array (COA) liquid crystal panel, comprising an array substrate, a glass substrate arranged opposite to the array substrate, and a liquid crystal layer arranged between the array substrate and the glass substrate;
wherein the array substrate comprises red, green, and blue sub pixel zones, each of the sub pixel zones comprising a base plate, an amorphous silicon layer formed on the base plate, a buffer layer formed on the amorphous silicon layer and the base plate, a poly-silicon layer formed on the buffer layer and corresponding to the amorphous silicon layer, a gate insulation layer formed on the poly-silicon layer and the buffer layer, a gate terminal formed on the gate insulation layer and corresponding to the poly-silicon layer, a scan line formed on the gate insulation layer, an interlayer insulation layer formed on the gate terminal, the scan line, and the gate insulation layer, source/drain terminals formed on the interlayer insulation layer, a signal line formed on the interlayer insulation layer and arranged to perpendicularly intersect the scan line in a horizontal direction, a passivation layer formed on the source/drain terminals, the signal line, and the interlayer insulation layer, a color resist layer formed on the passivation layer, a planarization layer formed on the color resist layer, and a pixel electrode layer formed on the planarization layer;
the interlayer insulation layer and the gate insulation layer comprise first vias formed therethrough at locations above the poly-silicon layer, the planarization layer, the color resist layer, and the passivation layer comprising a second via formed therethrough at a location above the source/drain terminals, the source/drain terminals being respectively set in engagement with the poly-silicon layer through the first vias, the pixel electrode layer being set in engagement with the source/drain terminals through the second via;
the color resist layer comprises red, green, and blue color resist blocks respectively corresponding to the red, green, and blue sub pixel zones, two of the color resist blocks that are arranged to be adjacent to each other in a lateral direction forming therebetween a first intersection zone, the first intersection zone being located above the signal line, two of the color resist blocks that are arranged to be adjacent to each other in a longitudinal direction forming therebetween a second intersection zone, the second intersection zone being located above the scan line, the pixel electrode layer comprising a pixel electrode block corresponding to the sub pixel zones, the pixel electrode block having a lateral border located above the scan line and a longitudinal border located above the signal line;
wherein the poly-silicon layer comprises a channel, two N-type light doping areas respectively located on opposite sides of the channel, and two N-type heavy doping areas respectively located on outer sides of the two N-type light doping areas, the first vias being arranged above and corresponding to the N-type heavy doping areas, the source/drain terminals being respectively connected by the first vias with the N-type heavy doping areas; and
wherein the planarization layer is formed of a transparent organic material.

12. The COA liquid crystal panel as claimed in claim 11, wherein the glass substrate comprises a common electrode layer formed thereon and the pixel electrode layer and the common electrode layer are both formed of a material of indium tin oxide.
